(19) United States
(12) Patent Application Publication
(10) Pub. No.: US 2019/0050153 A1
(43) Pub. Date: Feb. 14, 2019

(54) ROUTING DATA BLOCKS DURING THERMAL THROTTLING

(71) Applicant: Western Digital Technologies, Inc., San Jose, CA (US)

(72) Inventors: Nian Niles YANG, Mountain View, CA (US); Varuna KAMILA, San Jose, CA (US)

(21) Appl. No.: 15/672,260

(22) Filed: Aug. 8, 2017

(51) Int. Cl. G06F 3/06; G11C 7/04; G06F 1/20

(52) U.S. Cl. CPC G06F 3/0613; G06F 1/206; G11C 7/04; G06F 3/0614

(57) ABSTRACT

Embodiments of a SSD include a controller coupled to one or more flash dies, one or more temperature sensors proximate to the one or more flash dies, and data storing instructions. The one or more flash dies includes a plurality of TLC (triple level cell) blocks. The controller when executing the data storing instructions cause the controller to periodically fetch a temperature reading from the one or more temperature sensors and limit operations to the one or more flash dies when the temperature reading is above a start throttling threshold. In certain embodiments, TLC blocks are written to in a SLC mode when the temperature reading is above the start throttling threshold. In other embodiments, one or more spare SLC blocks are written to with non-system data during throttling.

### BACKGROUND OF THE DISCLOSURE

### Field of the Disclosure

Embodiments of the present disclosure generally relate to enhancing performance of SSDs in an event of thermal throttling.

### Description of the Related Art

Solid-state drives (SSDs) can contain a plurality of memory dies (e.g., in a multi-die package) that can be read or written in parallel. During read and write operations, SSDs consume power and generate heat. Very intensive or long-running, sustained workloads can cause a SSD to generate so much heat that it can exceed its optimal operating temperature. For example, sequential writes and sequential reads can cause the temperature of a SSD in a laptop to quickly rise from 20° C. to 80° C. in about two minutes of operation. To avoid burning out or damaging component of a SSD when the drive is at high temperatures, a controller of the SSD can perform a thermal throttling operation to reduce the SSD's temperature by slowing the throughput of the SSD. Reducing the throughput of a SSD allows overheating components of the SSD to cool down. Thermal throttling can include reducing die parallelism, inserting artificial delays in operational flows, and other actions.

Although thermal throttling of SSDs at high temperatures protects the drive, thermal throttling has an adverse impact on performance of the drive. For example, thermal throttling may cause a performance drop of a SSD to be 50% or more. Therefore, there is a need for an improved SSD and improved method of operating an SSD in the event of thermal throttling.

### SUMMARY OF THE DISCLOSURE

Embodiments of the present disclosure generally relate to enhancing performance of SSDs in an event of thermal throttling. Embodiments of a SSD include a controller coupled to one or more flash dies, one or more temperature sensors proximate to the one or more flash dies, and data storing instructions. The one or more flash dies include a plurality of TLC (triple level cell) blocks. The controller, when executing the data storing instructions that cause the controller to periodically fetch a temperature reading from the one or more temperature sensors, limits operations to the one or more flash dies when the temperature reading is above a start throttling threshold, and writes to the TLC blocks in a SLC mode when the temperature reading is above the start throttling threshold.

Embodiments of a method of storing data in a SSD, in which the SSD includes a plurality of memory dies, include periodically fetching a temperature of the memory dies. The memory dies include a plurality of multiple-bits-per-cell (MBC) blocks. Operations to the memory dies are throttled when the temperature is above a start throttling threshold. MBC blocks are written to in a single-bit-per-cell (SBC) mode during throttling.

In other embodiments, a method of storing data in a SSD, in which the SSD includes a non-volatile memory, includes periodically fetching a temperature of the non-volatile memory. The non-volatile memory includes a plurality of MBC blocks and a plurality of SBC blocks. Operations to the non-volatile memory are throttled when the temperature is above a start throttling threshold. One or more spare SBC blocks are scanned for from the plurality of SBC blocks when the temperature reading is above the start throttling threshold. The one or more spare SBC blocks are written to with non-system data during throttling.

In still other embodiments, a method of operating a solid state drive (SSD), in which the SDD includes a plurality of memory dies, includes periodically fetching a temperature of the memory dies. Operations to the memory dies are throttled when the temperature is above a start throttling threshold. Data is written to the blocks of the memory dies in a single-bit-per-cell (SBC) mode during throttling. The blocks written in the SBC mode are flagged.

In other embodiments, a SSD includes a controller coupled to a non-volatile memory means for storing data. The non-volatile memory means is capable to store data in a high-performance low-capacity mode and in a low-performance high-capacity mode. A temperature sensor is proximate to the non-volatile memory means. Memory storing data that, when executed by the controller, cause the controller to periodically fetch a temperature reading from the temperature sensor, throttle operations to the non-volatile memory means when the temperature reading is above a start throttling threshold, and write to the non-volatile memory means to store data in a high-performance low-capacity mode when the temperature reading is above the start throttling threshold.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic diagram of one embodiment of a SSD.

FIG. 2 is a schematic diagram of one example of a two dimensional memory array.

FIG. 3 is a schematic diagram of one example of a three dimensional memory array.

FIGS. 4A-4D are schematic diagrams of a memory cell storing a different number of bits.

FIG. 5 is a schematic diagram of one embodiment of a SSD with one enhanced performance in an event of thermal throttling.

FIG. 6 is a flowchart illustrating one embodiment of enhancing performance of a SSD device in an event of thermal throttling.

FIG. 7 is one embodiment of a block assignment table.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in the claim(s).

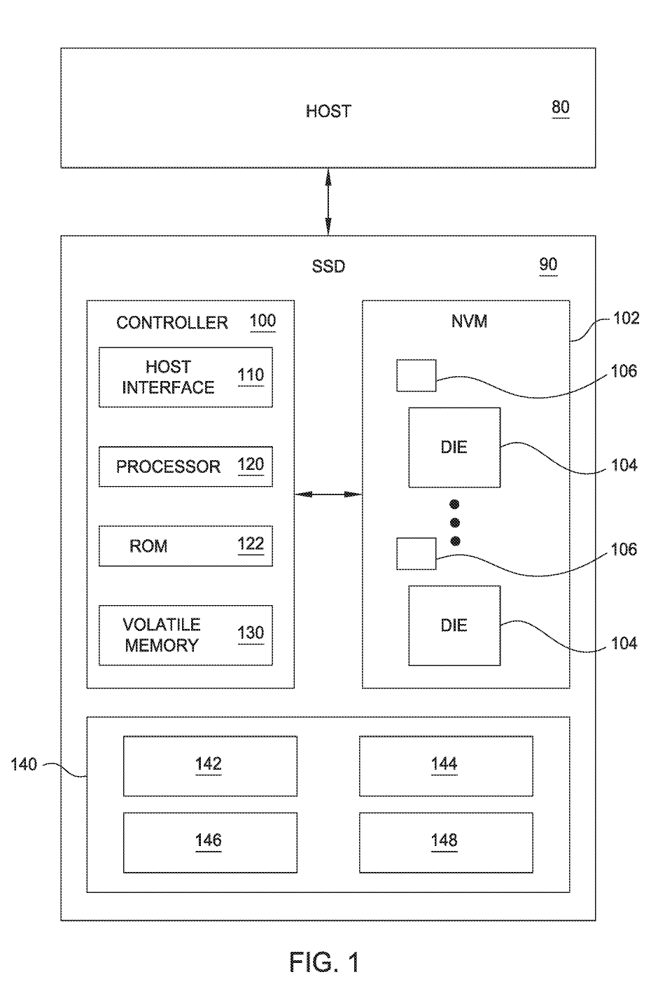

FIG. 1 is a schematic diagram of one embodiment of a SSD 90 suitable for implementing the present invention. The SSD 90 operates with a host 80 through a host interface 110. SSD 90 and host 80 may be coupled via a connection (e.g., a communication path), such as a bus or a wireless connection. SSD may be used as an embedded storage drive, an enterprise storage drive, a client storage device, a cloud storage drive, or in other applications. SSD 90 may be directly coupled to host 80 or may be indirectly coupled to host 80 via a network. For example, the network may include a data center storage system network, an enterprise storage system network, a storage area network, a cloud storage network, a local area network (LAN), a wide area network (WAN), the Internet, and/or another network.

SSD 90 may be in the form of a removable memory such as a memory card or may be in the form of an embedded memory system. SSD 90 may be a removable mass storage device, such as, but not limited to, a handheld, removable memory device, such as a memory card (e.g., a Secure Digital (SD) card, a micro Secure Digital (micro-SD) card, or a MultiMedia Card (MMC)), or a universal serial bus (USB) device. SSD 90 may take the form of an embedded mass storage device, such as an eSD/eMMC embedded flash drive, embedded in host 80.

Host 80 may include a wide range of devices, such as computer servers, network attached storage (NAS) units, desktop computers, notebook (i.e., laptop) computers, tablet computers (i.e., “smart” pad), set-top boxes, telephone handsets (i.e., “smart” phones), televisions, cameras, display devices, digital media players, video gaming consoles, video streaming devices, and automotive applications (i.e., mapping, autonomous driving). In certain embodiments, host 80 includes any device having a processing unit or any form of hardware capable of processing data, including a general purpose processing unit (such as a central processing unit (CPU)), dedicated hardware (such as an application specific integrated circuit (ASIC)), configurable hardware such as a field programmable gate array (FPGA), or any other form of processing unit configured by software instructions, microcode, or firmware.

Host 80 interacts with SSD 90 through host interface 110. In certain embodiments, host 80 and SSD 90 operates following the non-volatile memory express (NVMe), Universal Flash Storage (UFS), serial advanced technology attachment (SATA), serially attached SCSI (SAS), advanced technology attachment (ATA), parallel-ATA (PATA), Fibre Channel Arbitrated Loop (FCAL), small computer system interface (SCSI), peripheral component interconnect (PCI), PCI-express (PCIe), and other suitable protocols.

SSD 90 includes non-volatile memory (NVM) 102 controlled by a controller 100. NVM 102 includes one or more arrays of non-volatile memory cells. NVM 102 may be configured for long-term data storage of information and retain information after power on/off cycles. Non-volatile memory can include one or more memory devices. Examples of non-volatile memory devices include flash memories, phase change memories, ReRAM memories, MRAM memories, electrically programmable read only memories (EPROM), electrically erasable programmable read only memories (EEPROM), and other solid-state memories. Non-volatile memory device may also have different configurations. For example, flash memory devices may be configured in a NAND or a NOR configuration.

NVM 102 may include one or a plurality of dies 104 of NAND flash memory. NVM 102 may include one or a plurality of temperature sensor 106 proximate the one or a plurality of dies 104. For example, each die 104 may have a dedicated temperature sensor 106 for measuring the operating temperature of an individual die 104. Alternatively, two or more dies 104 may share a temperature sensor 106 for measuring the operating temperature of the group of dies 104.

Controller 100 also includes a processor 120, read-only-memory (ROM) 122, volatile memory 130, and additional components not shown. Controller 100 manages operations of SSD 90, such as writes to and reads from NVM 102. Processor 120 may be one or more processor or may be a multi-core processor. Controller 100 also includes volatile memory 130 or cache buffer(s) for short-term storage or temporary memory during operation of SSD 90. Volatile memory 130 does not retain stored data if powered off. Examples of volatile memories include random access memories (RAM), dynamic random access memories (DRAM), static random access memories (SRAM), and other forms of volatile memories.

Controller 100 executes computer-readable program code (e.g., software or firmware) executable instructions (herein referred to as “instructions”). The instructions may be executed by various components of controller 100, such as processor 120, logic gates, switches, application specific integrated circuits (ASICs), programmable logic controllers, embedded microcontrollers, and other components of controller 100.

The instructions are stored in a non-transitory computer readable storage medium. In certain embodiment, the instructions are stored in a non-transitory computer readable storage medium of SSD 90, such as in ROM 122 or NVM 102. Instructions stored in SSD 90 may be executed without added input or directions from host 80 and may enable high input/output operations per second of SSD 90 since SSD 90 does not need to wait to receive extra commands from host 80 besides normal read, write, and/or erase commands from host 80. Execution of instructions stored in SSD 90 is seamless to host 80. In other embodiments, the instructions are stored in a non-transitory computer readable storage medium of host 80. The stored instructions, such as stored in SSD 90 or host 80, may be loaded in full or in part into volatile memory 130 of controller 100 for execution by controller. The controller 100 is configured with hardware and instructions to perform the various functions described herein and shown in the figures.

SSD 90 may further include a flash translation layer 140. Flash translation layer 140 may be stored in NVM 102 and loaded or partially loaded to volatile memory 130. Flash translation layer may include a logical to physical (or virtual to physical) data address/container/sector translation mapping 142. Host device 80 may refer to a unit of data using a logical data address, and controller 110 may utilize mapping 142 to direct writing of data to and reading of data from NVM 102. Flash translation layer 140 may include garbage collection tables 144 to move valid data from a selected block having invalid data to an open block or to a partially filled block and erasing the selected block. Flash translation layer 140 may include a wear leveling counter 146 to record the number of program erase cycles of a block to level the usage of the blocks of NVM 102. Flash translation layer 140 may include a free block list which lists the blocks that are open for programming or available for programming.

NVM 102 may include multiple memory cells configured to be accessed as a group or accessed individually. For example, flash memory devices in a NAND configuration typically contain memory cells connected in series. A NAND memory array may be configured so that the array is composed of multiple strings of memory in which a string is composed of multiple memory cells sharing a single bit line and accessed as a group. Alternatively, memory elements may be configured so that each element is individually accessible, such as in a NOR configuration. Memory configurations other than NAND or NOR memory configurations are possible.

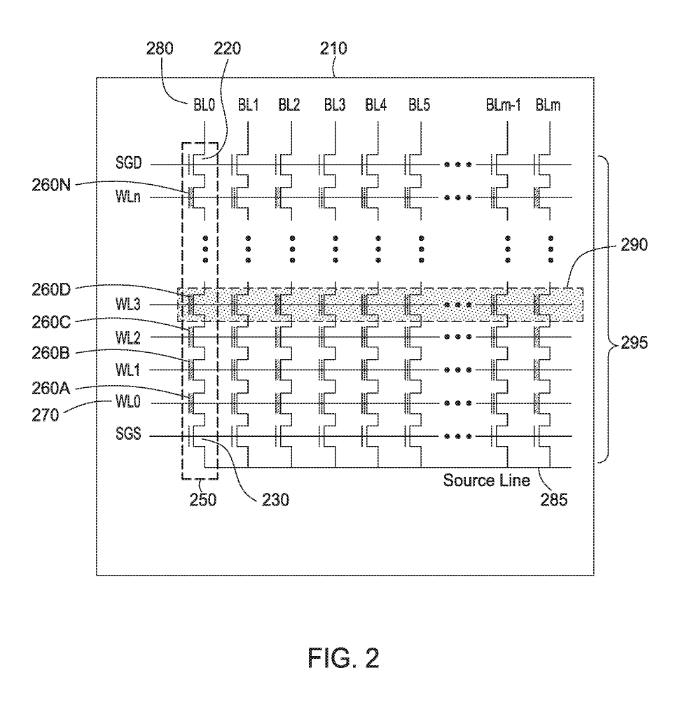

The memory cells may be arranged in two or three dimensions, such as a two dimensional memory array or a three dimensional memory array. FIG. 2 is a schematic diagram of one example of a two dimensional memory array 210, such as a 2D or planar NAND memory array. The memory array 210 includes a set of NAND strings 250. Each NAND string 250 comprises a memory cells 260A, 260B, 260C, 260D to 260N. Each NAND string 250 includes a select gate drain transistor (SGD) 220 and a select gate source transistor (SGS) 230. The memory array 210 includes multiple pages 290. Page 290 is accessed by the control gates of the cells of the page connected in common to a word line 270 and each cell accessible via bit lines 280. A source line 285 is also present. In other embodiments, the memory cells may be arranged in other configurations.

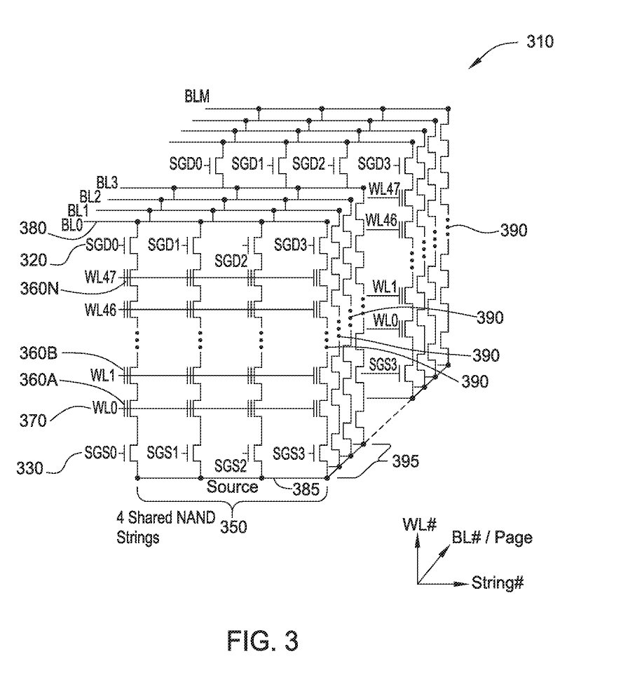

FIG. 3 is a schematic diagram of one example of a three dimensional memory array 310, such as a 3D or vertical NAND memory array or a BiCS2 cell array as shown. Memory array 310 is made up of a plurality of pages 390. Each page 390 includes a set of NAND strings 350 (four NAND strings are shown). Each set of NAND strings 350 is connected in common to a global bit line 380. Each NAND string 350 includes a select gate drain transistor (SGD) 320, a plurality of memory cells 360A, 360B, 360N, and a select gate source transistor (SGS) 330. A row of memory cells is connected in common to a word line 370. A source line 385 is also present.

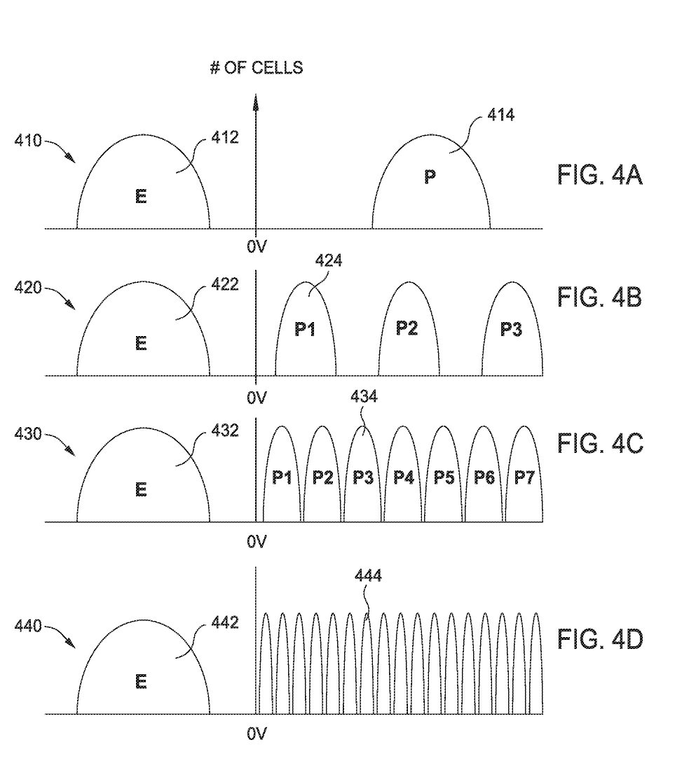

The memory cells 260, 360 shown in FIGS. 2 and 3 are made up of a transistor that has a charge storage element to store a given amount of charge representing a memory state. FIGS. 4A-4D are schematic diagrams of a memory cell, such as such as memory cells 260, 360 of FIG. 2 and FIG. 3, storing a different number of bits. FIG. 4A is a schematic diagram 410 of a memory cell operating as single-level cell (SLC) memory cell to store one bit per cell. The SLC memory cell may be operated with two threshold voltage distribution states representing an erased state 412 and a programmed state 414. FIG. 4B is a schematic diagram 420 of a memory cell operating as a multi-level cell (MLC) or X2 cell storing 2 bits/cell. The MLC memory cell may be operated with four threshold voltage states representing an erased state 422 and three programmed states 424. FIG. 4C is a schematic diagram 430 of a memory cell operating as a triple-level cell (TLC) or X3 cell storing 3 bits/cell. The TLC memory cell may be operated with eight threshold voltage states representing an erased state 432 and seven programmed states 434. FIG. 4D is a schematic diagram 440 of a memory cell operating as a quadruple-level memory cell (QLC) or X4 cell storing 4 bits/cell. The QLC memory cell may be operated with sixteen threshold voltage states representing an erased state 442 and fifteen programmed states 444.

The blocks of dies 104 of SSD 90 may be organized to store a single bit per cell (herein referred to as single-bit-per-cell or SBC) or to store multiple bits per cell (herein referred to as multiple-bits-per-cell or MBC). SBC blocks include blocks configured to store one bit per cell, such as SLC blocks. MBC blocks include blocks configured to store two bits or more per cell such as MLC blocks, TLC blocks, or QLC blocks. For example, BiCS3 flash dies may be configured as 1,350 TLC blocks and 64 SLC blocks. SBC blocks may be used to store system data, which may include, but are not limited to, BIOS, firmware, flash translation layer, mapping tables. MBC blocks may be used to store non-system data. SBC blocks may be reserved for system data so that system data is stored in a higher endurance memory and may be read more rapidly.

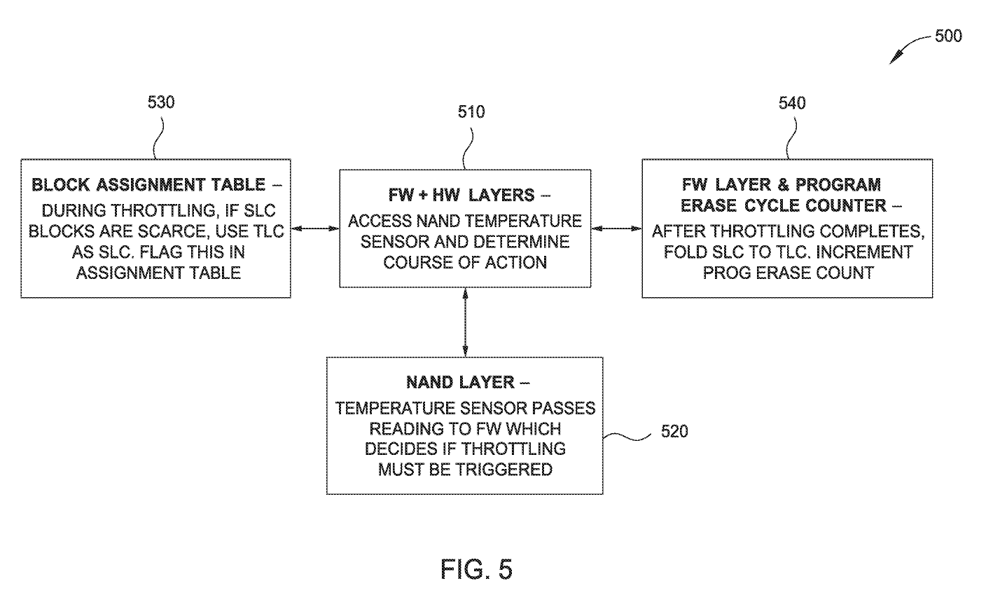

FIG. 5 is a schematic diagram of one embodiment of a SSD 500 with enhanced performance in an event of thermal throttling. System 500 is described in reference to SSD 90 of FIG. 1 but other SSDs are possible. System 500 includes sub-system 510, sub-system 520, sub-system 530, and sub-system 540, but other sub-systems and configurations are possible.

Sub-system 510 includes a firmware and hardware layer, such as controller 100 of FIG. 1, coupled or connected to sub-system 520, sub-system 530, and sub-system 540. Sub-system 520 includes a NAND layer of one or a plurality dies of NAND flash memory cells, such as dies 104 of FIG. 1. Each die 104 may include a temperature sensor, such as temperature sensor 106 of FIG. 1, or two or more dies 104 may share a temperature sensor. Each die 104 contains a plurality of blocks, such as blocks 295 of FIG. 2 and/or blocks 395 of FIG. 3. Each block may be operated so that the memory cells store a certain number of bits per cell, such as in FIGS. 4A-4D. Sub-system 520 may include a plurality of MBC blocks and a plurality of SBC blocks.

Sub-system 510 accesses the temperature sensor of the NAND flash dies of sub-system 520. If sub-system 510 detects that a temperature reading of the temperature sensor is above a start throttling threshold, sub-system 510 implements a thermal throttling operation by limiting operations to the flash dies. During thermal throttling, sub-system 510 may conduct write operations of non-system data to spare SBC blocks less than the total configured SBC blocks. In certain embodiments, a certain number of SBC blocks are not used during thermal throttling to store non-system data so that system data may be stored to SBC blocks, if necessary. During thermal throttling, if SBC blocks are not available, then sub-system 510 selects MBC blocks and conducts writes to these MBC blocks in a SBC mode. For example, controller may select a TLC block and program the selected TLC block in a SLC mode.

By writing to a SBC block during thermal throttling or writing to a MBC block in a SBC mode during thermal throttling, less heat is generated in writing in a SBC mode in comparison to a MBC mode. For example, writing a page of a block in a SLC mode generates less heat than writing a page of a block in a TLC mode. In addition, writing to blocks in a SBC mode is faster in comparison to writing in a MBC mode. For example, writing a page of block in a SLC mode is faster in comparison to writing a page of a block in a TLC mode. Due to the less heater generated and/or faster programming, sub-system 520 may require less time to reduce its temperature below a stop thermal throttling threshold and more rapidly return to normal operations. In addition, during thermal throttling, faster writes in a SBC mode in comparison to a MBC mode reduces the impact to performance caused by thermal throttling.

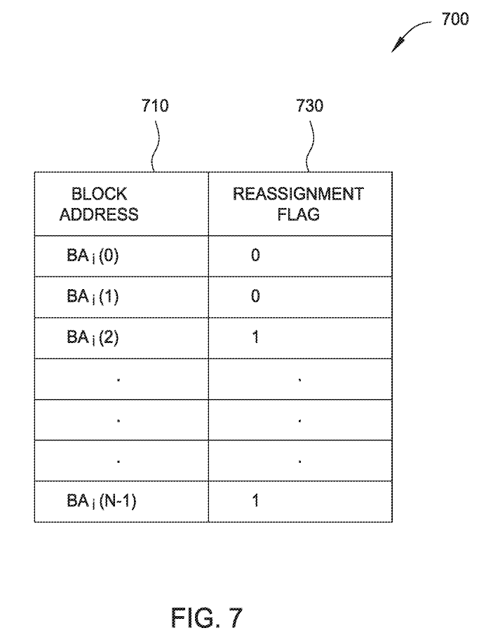

Sub-system 530 includes a block assignment table, such as a block assignment table 700 of FIG. 7. As shown in FIG. 7, block assignment table 700 may include block addresses/ranges 710 corresponding to a logical block address (LBA) and/or a physical block address (PBA). Sub-system 510 may use the block assignment table 700 to include a reassignment flag 730. The reassignment flag 730 may indicate the SBC blocks written to during thermal throttling and/or the MBC blocks written to in a SBC mode during thermal throttling. For example, sub-system 510 may use the block assignment table in sub-system 530 to flag the TLC blocks written to in SLC mode during thermal throttling. The block assignment table be may be stored in sub-system 520 and loaded to volatile memory of subsystem 510.

Sub-system 510 may use the block assignment table during read operations of MBC blocks storing data in a SBC mode to decode the stored data in a SBC mode. Sub-system 510 may use the block assignment table to identify the SBC blocks storing non-system data to be folded into MBC blocks to maintain the capacity to store system data. Sub-system 510 may use the block assignment table to identify MBC blocks storing data in a SBC mode to be folded into MBC blocks in a MBC mode to maintain the storage capacity of the SSD.

Sub-system 540 may include a firmware layer containing instructions that after thermal throttling completes or when sub-system 510 detects that a temperature reading of the temperature sensor is below a stop throttling threshold, the SBC blocks storing non-system data may be folded into MBC blocks to maintain the capacity to store system data, and/or MBC blocks storing data in a SBC mode may be folded into MBC blocks in a MBC mode to maintain the storage capacity of the SSD. Sub-system 540 may also include a firmware layer containing instructions to increment forward a program erase cycle counter of the folded blocks, such as incrementing forward the wear leveling counter 146 of FIG. 1.

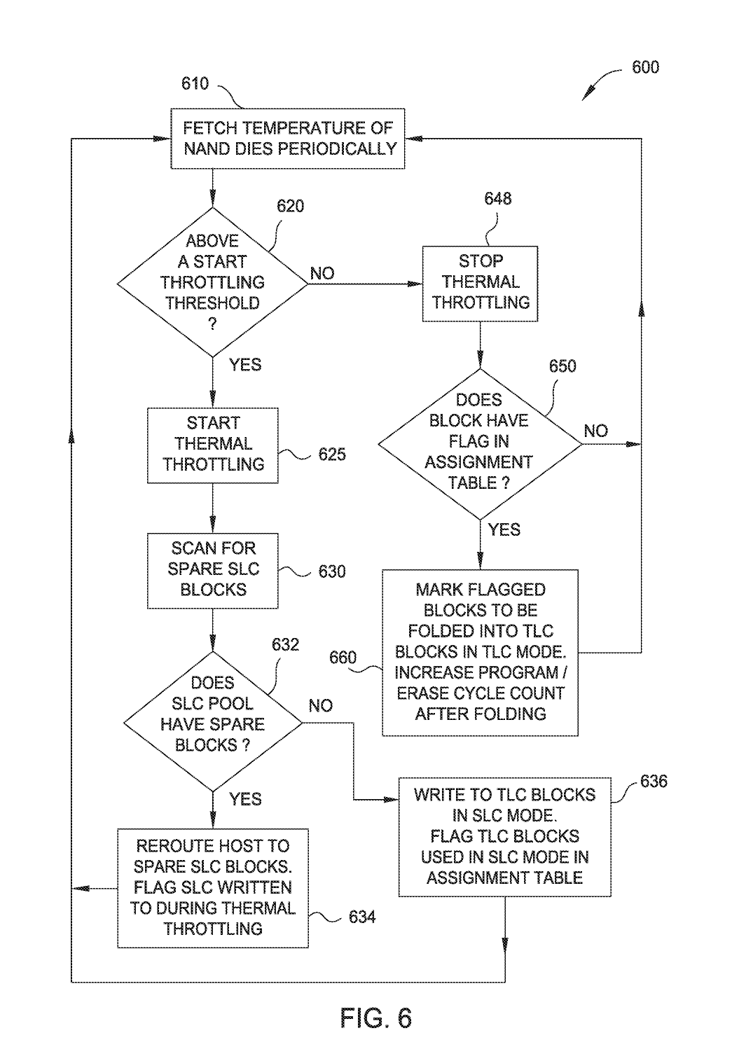

FIG. 6 is a flowchart 600 illustrating one embodiment of storing data in a SSD device in an event of thermal throttling. Flowchart 600 is described in reference to SSD 90 of FIG. 1, but other SSDs are possible. One or more blocks of flowchart 600 may be performed by controller 100 executing computer-readable program code (e.g., software or firmware) executable instructions stored in SSD 90 or host 80. Flowchart 600 is described in reference to MBC blocks of TLC blocks, but other MBC blocks may be used, such as MLC blocks and/or QLC blocks.

At process 610, controller periodically fetches a temperature of the NAND die(s) by receiving a temperature reading from temperature sensor 106. For example, controller may fetch the temperature of the NAND dies every 1 second or any appropriate interval. Each die may include a temperature sensor, such as temperature sensor 106 of FIG. 1, or two or more dies may share a temperature sensor.

At process 620, controller determines if the temperature reading is above a start throttling threshold or if the temperature reading is below a stop throttling threshold. If the temperature reading is above a start throttling threshold (such as 80° C. or more), control proceeds to process 625 in which thermal throttling is started. If the temperature is below a stop throttling threshold (such as 75° C. or below), controller proceeds to process 648 in which thermal throttling is stopped. A start throttling threshold and a stop throttling threshold may be set to any appropriate temperature(s). In other embodiments, a start throttling threshold and a stop throttling threshold may be about the same temperature.

At process 625, operations to the NAND dies 104 are throttled to protect or reduce damage to the NAND dies and other components of SSD 90. Throttling may include limiting the number of active operations to the NAND dies, such as limiting the number of active read, writes, and/or erasures to the blocks of the NAND dies.

At process 630, the controller scans a SLC block free pool, such as a free block list 148 of FIG. 1, for available spare SLC blocks to store non-system data. A certain number of SBC blocks are not used to store non-system data during thermal throttling so that system data may be stored to SBC blocks, if necessary. In certain embodiments, the available spare SLC blocks are less than the total available SBC blocks.

At process 632, the controller determines if there are or are not available spare SLC blocks from process 630. If there are available spare SLC blocks, controller proceeds to process 634. If there are not available spare SLC blocks, controller proceeds to process 636.

At process 634, the controller reroutes queued or received host writes intended to TLC block(s) to available spare SLC block(s). The controller may update the assignment table, such as assignment table 700 of FIG. 7, with a reassignment flag to indicate the spare SLC blocks written to during thermal throttling.

At process 636, controller routes queued or received host writes to TLC blocks and writes to the TLC blocks in a SLC mode. The controller may update the assignment table, such as assignment table 700 of FIG. 7, with a reassignment flag to indicate the TLC blocks written to in a SLC mode during thermal throttling.

If the temperature is below a stop throttling threshold (such as 75° C. or below) at process 620, the controller proceeds to process 648 in which thermal throttling is stopped. After thermal throttling is stopped, SSD 90 operates under normal or full system performance. The controller then proceeds to process 650.

At process 650, when SSD 90 is not under thermal throttling, the controller scans for blocks that are marked with a reassignment flag from process 634 and/or from process 636. If there is a reassignment flag, the controller proceeds to process 660.

At process 660, the controller folds or marks blocks to be folded into TLC blocks in a TLC mode. For example, SLC blocks written to at process 634 may be folded into TLC blocks in a TLC mode to maintain the capacity to store system data. TLC blocks written to in a SLC mode at process 636 may be folded into TLC blocks in a TLC mode to maintain the storage capacity of the SSD. A program erase cycle counter of the folded blocks may be incremented forward, such as incrementing forward the wear leveling counter 146 of FIG. 1. After the blocks are folded into TLC blocks, the reassignment flags of the folded blocks is removed or reset from the assignment table.

As shown in flowchart 600, at the end of process 634, process 636, process 650 if there are not blocks with a reassignment flag, and process 660, the controller proceeds back to process 610. In is understood that in other embodiments, fetching of the temperature of the NAND dies occurs periodically to start and/or stop thermal throttling and need not wait for the end of any processes of flowchart 600.

FIG. 7 is one embodiment of a block assignment table 700 which may be used in SSD 500 of FIG. 5 and in the flowchart 600 of FIG. 6. Table 700 includes block addresses 710 and reassignment flags 730. Block addresses 710 may correspond to a logical block addresses (LBA) and/or a physical block addresses (PBA). The reassignment flag 730 may indicate the SBC blocks written to during thermal throttling and/or the MBC blocks written to in a SBC mode during thermal throttling. The reassignment flat entry may consume as little as one bit of memory. The reassignment flag may be a “1” entry and a non-reassignment flag as a “0” entry. Alternatively, the reassignment flag may be a “0” entry and a non-reassignment flag as a “1” entry. Reassignment flags 730 may be used by a controller in read operations of MBC blocks written to a SBC mode. Reassignment flag 730 may be used by a controller to fold or to mark to be folded blocks written in a SBC mode to MBC blocks in a MBC mode.

The block assignment table 700 may be used by a flash translation layer or may be incorporated into a flash translation layer, such as flash translation layer 140 of FIG. 1. For example, in one embodiment, the block assignment table may be incorporated into a logical block address to physical block address mapping of the flash translation layer. In another embodiment, the block assignment table may be incorporated into a garbage collection module to fold blocks during garbage collection.

In certain embodiments, a SSD is operated with less heat generated during programming and improved performance during thermal throttling. In certain aspects, a SSD under thermal throttling has improved performance by faster programming of data blocks during thermal throttling, such as programming in SLC mode rather than TLC mode.

In certain embodiments, programming in a SBC mode generates less heat than programming in a MBC mode. For example, programming memory cell in a HBC mode may require multiple passes or multiple programmings to achieve the final program state resulting in greater heat generated. For example, the approximate amount of current I_{CC} consumed on average by a TLC block in a TLC mode is about 40 milliamperes while the approximate amount of current I_{CC} consumed on average by a SLC block in a SLC mode is about 20 milliamperes. Assuming the same voltage V_{CC}, TLC blocks in a TLC mode consume about twice the amount of power during operation and must dissipate about twice the amount of heat on a block basis in comparison to SLC blocks in a SLC mode.

Since less heat is generated by programming in a SBC mode during thermal throttling rather than programming in a MBC mode, a SSD may cool more rapidly below a stop throttling threshold temperature and may have a reduce time under thermal throttling (i.e., coming out of thermal throttling more rapidly). In certain embodiments, although a SSD is operated under thermal throttling, less deterioration of performance of the SSD and lower heating of SSD is achieve by programming in a SBC mode, such as programming of spare SBC blocks and/or programming of MBC blocks in a SBC mode.

In certain embodiments, a capacity of a SSD is maintained by folding the blocks written to in a SBC mode during thermal throttling into MBC blocks in a MBC mode when the SSD is not under thermal throttling. For example, folding spare SLC blocks written to during thermal throttling and/or folding TLC blocks written to in a SLC mode into TLC blocks in a TLC mode when the SSD is not under thermal throttling.

In certain embodiments of a NAND flash BiCS die, a BiCS die cools about 1° C./sec under thermal throttling and programming in a SBC mode. Therefore, in certain embodiments depending on the memory die, if a start thermal threshold is 80° C. and a stop thermal throttling threshold is 75° C., the time to come out of thermal throttling by programming in a SBC mode is about 5 seconds to resume full non-throttled performance.

In certain embodiments, programming in a SBC mode during thermal throttling provides a lower bit error rate. Decoding of cells programmed in a SBC mode may be less complicated than decoding of cells programmed in a MBC mode. Cells programmed in a SBC mode may be impacted less by cross-temperature variations in which the threshold voltage of a programmed cell shifts from a different write temperature and read temperature than cells programmed in a MBC mode.

In certain embodiments, a greater size of data may be programmed in SBC mode than programming under MBC mode when the SSD is under thermal throttling For example, programming a page in a SLC block may take about 170 microseconds while programming a page in a TLC may take about 1,000 microseconds. Therefore, five or more pages of a SLC block may be programmed in the time it takes to program one page of a TLC blocks.

In certain embodiments, an improved processes and an improved SSD of storing data under thermal throttling does not require any configuration changes to the host. In certain embodiments, an improved processes and an improved SSD of storing data under thermal throttling is seamless to the host in that host data writes are written in a SBC or MBC mode without directions from the host on which mode to use.

Embodiments of the present disclosure in FIGS. 2-6 have been described in reference to NAND flash memory cells. Embodiments of the present disclosure are applicable to any non-volatile memory that may be operated in a SBC mode and a MBC mode, such as NOR flash memory cells, resistive random access memory (ReRAM), and phase change memory (PCM). Memory cells operated in a SBC mode may have higher performance (such as faster programming and/or better endurance) but lower capacity than memory cells operated in a MBC mode. Embodiments of the present disclosure include writing to non-volatile memory in a high-performance low-capacity mode during thermal throttling and in a low-performance high-capacity mode outside of thermal throttling Embodiments of the present disclosure include folding data stored a high-performance low-capacity mode to a low-performance high-capacity mode outside of thermal throttling.

While the foregoing is directed to embodiments of the present disclosure, other and further embodiments of the disclosure may be devised without departing from the basic scope thereof, and the scope thereof is determined by the claims that follow.

What is claimed is:

1. A solid state drive, comprising:
a controller;
one or more flash dies comprising a plurality of triple level cell (TLC) blocks;
one or more temperature sensors proximate to the one or more flash dies; and
a non-transitory computer readable storage medium containing data storing instructions that, when executed by the controller, cause the controller to:
periodically fetch a temperature reading from the one or more temperature sensors;
limit operations to the one or more flash dies when the temperature reading is above a start throttling threshold; and
write to the TLC blocks in a SLC mode when the temperature reading is above the start throttling threshold.

2. The solid state drive of claim 1, further comprising an assignment table wherein the data storing instructions further cause the controller to flag in the assignment table the TLC blocks written in the SLC mode.

3. The solid state drive of claim 1, wherein the data storing instructions further cause the controller to fold the TLC blocks written in the SLC mode into TLC blocks in a TLC mode when the temperature reading is below a stop throttling threshold.

4. The solid state drive of claim 3, wherein the data storing instructions further cause the controller to increase a program-erase count of the folded TLC blocks.

5. The solid state drive of claim 1, wherein the one or more flash dies further comprise a plurality of single level cell (SLC) blocks and wherein the data storing instructions further cause the controller to scan for one or more spare SLC blocks from the plurality of SLC blocks when the temperature reading is above the start throttling threshold.

6. The solid state drive of claim 5, wherein the data storing instructions further cause the controller to write to the one or more spare SLC blocks prior to the write to the TLC blocks when the temperature reading is above the start throttling threshold.

7. A method of storing data in a solid state drive (SSD), the SSD comprising a plurality of memory dies, the memory dies comprising a plurality of multiple-bits-per-cell (MBC) blocks, the method comprising:
periodically fetching a temperature of the memory dies;
throttling the memory dies when the temperature is above a start throttling threshold; and
writing to MBC blocks in a single-bit-per-cell (SBC) mode during throttling.

8. The method of claim 7, further comprising flagging the MBC blocks written to in the SBC mode.

9. The method of claim 7, further comprising folding the MBC blocks written to in the SBC mode into MBC blocks in a MBC mode when the temperature is below a stop throttling threshold.

10. The method of claim 9, further increasing a program-erase count of the folded MBC blocks.

11. The method of claim 7, wherein the plurality of memory dies further comprises a plurality of SBC blocks, the method further comprising scanning for one or more spare SBC blocks from the plurality SBC blocks during throttling.

12. The method of claim 11, further comprising writing to the spare SBC blocks prior to the writing to the MBC blocks during throttling.

13. A method of storing data in a solid state drive (SSD), the SSD comprising a non-volatile memory, the non-volatile memory comprising a plurality of multiple-bits-per-cell (MBC) blocks and a plurality of single-bit-per-cell (SBC) blocks, the method comprising:
periodically fetching a temperature of the non-volatile memory;
throttling the non-volatile memory when the temperature is above a start throttling threshold;
scanning for one or more spare SBC blocks from the plurality of SLC blocks when the temperature reading is above the start throttling threshold; and
writing to the one or more spare SBC blocks with non-system data during throttling.

14. The method of claim 13, wherein writing to the one or more spare SBC blocks comprises rerouting writing of MBC blocks to the one or more spare SBC blocks.

15. The method of claim 13, further comprising flagging spare SBC blocks written to with non-system data during throttling.

16. The method of claim 13, wherein the MBC blocks are TLC blocks and the SBC blocks are SLC blocks.

17. The method of claim 13, further comprising folding spare SBC blocks written to with non-system data during throttling into MBC blocks when the temperature reading is below a stop throttling threshold.

18. The method of claim 17, further comprising increasing a program-erase count of the folded SBC blocks with non-system data.

19. A memory storage system, comprising:
a controller means;
a non-volatile memory means for storing data; the non-volatile memory means capable to store data in a high-performance low-capacity mode and in a low-performance high-capacity mode;
a temperature sensor proximate to the non-volatile memory means; and
a non-transitory computer readable storage medium containing data storing instructions that, when executed by the controller means, cause the controller to:
periodically fetch a temperature reading from the temperature sensor;
throttle operations to the non-volatile memory means when the temperature reading is above a start throttling threshold; and
write to the non-volatile memory means to store data in a high-performance low-capacity mode when the temperature reading is above the start throttling threshold.

20. The memory storage system of claim 19, wherein the data storing instructions further cause the controller means to fold data stored in the high-performance low-capacity mode into the low-performance high-capacity mode when the temperature reading is below a stop throttling threshold.

21. The memory storage system of claim 19, wherein the blocks operating in the high-performance low capacity mode generates less heat than the blocks operating in the low-performance high-capacity mode.

22. The memory storage system of claim 19, wherein the data storing instructions further cause the controller means to write data faster in the high-performance low capacity mode than the low-performance high-capacity mode.

23. A method of operating a solid state drive (SSD), the SSD comprising a plurality of memory dies, the memory dies comprising a plurality of blocks, the method comprising:
periodically fetching a temperature of the memory dies;
throttling the memory dies when the temperature is above a start throttling threshold;
writing data to the blocks in a single-bit-per-cell (SBC) mode during throttling; and
flagging the blocks written in the SBC mode.

24. The method of claim 23, further comprising decoding the written data in a read operation by determining whether the blocks have been flagged in the SBC mode.

25. The method of claim 23, further comprising folding the blocks written in the SBC mode into the blocks in a multiple-bits-per-cell (MBC) mode when the temperature is below a stop throttling threshold.

26. The method of claim 25, wherein folding the blocks comprises determining whether the blocks have been flagged in the SBC mode.
